(19) United States
(12) Patent Application Publication
(10) Pub. No.: US 2024/0429180 A1
(43) Pub. Date: Dec. 26, 2024

(54) SEMICONDUCTOR DEVICE AND METHOD FOR PRODUCING SEMICONDUCTOR DEVICE

(71) Applicant: FUJI ELECTRIC CO., LTD., Kawasaki-shi (JP)

(72) Inventor: Mai SAITO, Matsumoto-city (JP)

(73) Assignee: FUJI ELECTRIC CO., LTD., Kawasaki-shi (JP)

(21) Appl. No.: 18/646,103

(22) Filed: Apr. 25, 2024

(30) Foreign Application Priority Data
Jun. 20, 2023 (JP) 2023-100880

(51) Int. Cl. H01L 23/00; H01L 21/56; H01L 23/29; H01L 23/31; H01L 23/373; H01L 23/498

(52) U.S. Cl. CPC H01L 23/564; H01L 21/56; H01L 23/3135; H01L 23/3735; H01L 23/293; H01L 23/295; H01L 23/3121; H01L 23/49811; H01L 24/32; H01L 24/33; H01L 2224/32225; H01L 2224/32245; H01L 2224/33181; H01L 2924/13055

(57) ABSTRACT

A semiconductor device includes: a semiconductor module including a semiconductor chip; a cooler configured to cool the semiconductor module; a thermal conductive layer interposed between the semiconductor module and the cooler; and a protective film covering: a boundary between the semiconductor module and the thermal conductive layer; and a boundary between the cooler and the thermal conductive layer, in which the protective film has a water absorption rate that is less than a water absorption rate of the thermal conductive layer.

### CROSS REFERENCE TO RELATED APPLICATION

This Application is based on, and claims priority from, Japanese Patent Application No. 2023-100880, filed on Jun. 20, 2023, the entire contents of which are incorporated herein by reference.

### BACKGROUND

### Technical Field

This disclosure relates to semiconductor devices.

### Related Art

Semiconductor devices have been proposed that include a plurality of power semiconductor chips including, for example, an insulated gate bipolar transistor (IGBT) or a metal oxide semiconductor field effect transistor (MOSFET) as disclosed in (1) Japanese Patent No. 7154422, (2) Japanese Patent No. 7134360, and (3) Japanese Patent Application Laid-Open Publication No. 2020-098882. For example, Japanese Patent No. 7154422 discloses a power semiconductor device in which a module and a cooler are bonded by an insulated resin material to each other. In a configuration disclosed by Japanese Patent No. 7154422, moisture may infiltrate into a boundary between the insulated resin material and the module or into a boundary between the insulated resin material and the cooler. The moisture that has infiltrated may cause reduction in bonding of the module to the cooler or may cause reduction in dielectric strength voltage of the insulated resin material.

### SUMMARY

An object of one aspect according to this disclosure is to reduce infiltration of moisture into an object (or into gaps) interposed between a semiconductor module and a cooler.

A semiconductor device according to one aspect of this disclosure includes: a semiconductor module including a semiconductor chip; a cooler configured to cool the semiconductor module; a thermal conductive layer interposed between the semiconductor module and the cooler; and a protective film covering: a boundary between the semiconductor module and the thermal conductive layer; and a boundary between the cooler and the thermal conductive layer, in which the protective film has a water absorption rate that is less than a water absorption rate of the thermal conductive layer.

A semiconductor device according to another aspect of this disclosure includes: a semiconductor module including a semiconductor chip; a cooler configured to cool the semiconductor module; a thermal conductive layer interposed between the semiconductor module and the cooler; and a protective film covering: a boundary between the semiconductor module and the thermal conductive layer; and a boundary between the cooler and the thermal conductive layer, in which the protective film has a thickness that is less than a distance between the semiconductor module and the cooler.

A method for producing a semiconductor device according to yet another aspect of this disclosure includes: bonding a semiconductor module including a semiconductor chip to a cooler configured to cool the semiconductor module by a thermal conductive layer interposed between the semiconductor module and the cooler; and forming a protective film covering: a boundary between the semiconductor module and the thermal conductive layer; and a boundary between the cooler and the thermal conductive layer.

### BRIEF DESCRIPTION OF THE DRAWINGS

FIG. 1 is a cross section of a semiconductor device according to a first embodiment.

FIG. 2 is an enlarged cross section of a vicinity (region a shown in FIG. 1) of an outer peripheral edge of a semiconductor module.

FIG. 3 is an explanatory diagram showing a process of producing the semiconductor device.

FIG. 4 is a cross section of the semiconductor device according to a second embodiment.

FIG. 5 is an explanatory diagram showing a process of producing the semiconductor device according to the second embodiment.

FIG. 6 is an enlarged cross section of a vicinity of the outer peripheral edge of the semiconductor module of the semiconductor device according to a third embodiment.

FIG. 7 is a cross section of the semiconductor device according to a modification.

### DESCRIPTION OF EMBODIMENTS

Embodiments according to this disclosure will now be described with reference to the accompanying drawings. In each drawing, dimensions and scales of elements may differ from those of actual products. In addition, each embodiment described below is an exemplary embodiment assumed in a case in which this disclosure is implemented. Thus, the scope of this disclosure is not limited to the embodiments described below.

### A: First Embodiment

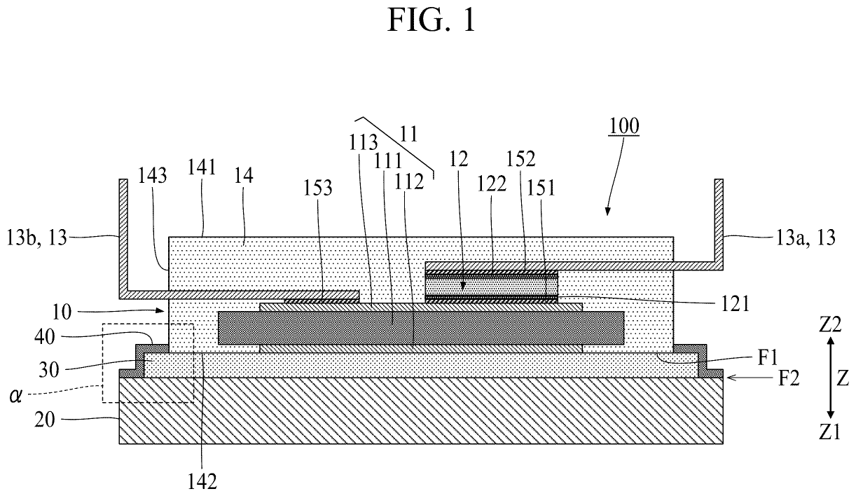

FIG. 1 is a cross section of a semiconductor device 100 according to a first embodiment. The semiconductor device 100 according to the first embodiment is, for example, a power semiconductor device included in a power conversion apparatus such as an inverter circuit. As shown in FIG. 1, the semiconductor device 100 includes a semiconductor module 10, a cooler 20, a thermal conductive layer 30, and a protective film 40.

In the following description, a Z-axis is defined. A direction along the Z-axis is referred to as a direction Z1, whereas a direction opposite to the direction Z1 is referred to as a direction Z2. In the following description, viewing an element, which is freely selected from elements of the semiconductor device 100, along a direction of the Z-axis (Z1 direction or Z2 direction) is referred to as a “plan view.”

In actual use, the semiconductor device 100 may be disposed in any direction. However, in the following description, the direction Z1 is assumed to be a downward direction, and the direction Z2 is assumed to be an upward direction, for convenience. Thus, a surface facing in the direction Z1 among a plurality of surfaces of the semiconductor device 100 may be referred to as a “lower surface,” whereas a surface facing in the direction Z2 among the plurality of surfaces of the semiconductor device 100 may be referred to as an “upper surface.”

The semiconductor module 10 is a power module that includes a mounting substrate 11, a semiconductor chip 12, a plurality of connection terminals 13, and an encapsulant 14. The semiconductor chip 12 and the plurality of connection terminals 13 are disposed on the mounting substrate 11, and the semiconductor chip 12 is encapsulated by the encapsulant 14. In the following description, one semiconductor chip 12 is focused on. However, a plurality of semiconductor chips 12 may be disposed on the mounting substrate 11.

The mounting substrate 11 is an insulated substrate such as a direct copper bonding (DCB) substrate, an active metal brazing (AMB) substrate, or an insulated metal substrate (IMS), etc. Specifically, the mounting substrate 11 includes a stack of an insulated substrate 111, a metallic layer 112, and a conductive pattern 113.

The insulated substrate 111 is a rectangular plate-shaped member made of an insulation material. The insulated substrate 111 is made of a resin material such as an epoxy resin material including ceramic fillers, for example. Alternatively, the insulated substrate 111 may be made of a ceramic material such as aluminum oxide, zirconium oxide, aluminum nitride, or silicon nitride, etc.

The metallic layer 112 is a rectangular plate-shaped member disposed on a lower surface of the insulated substrate 111. The metallic layer 112 is made of a metallic material with high thermal conductivity. The material of the metallic layer 112 is freely selected. The material of the metallic layer 112 may be a copper material alone, an alloy of copper, or an aluminum material, etc.

The conductive pattern 113 is a conductive film disposed on an upper surface of the insulated substrate 111. The conductive pattern 113 is constituted of a plurality of patterns made of a low-resistance conductive material. The material of the conductive pattern 113 is freely selected. The material of the conductive pattern 113 may be a copper material alone, an alloy of copper, or an aluminum material, etc.

The semiconductor chip 12 is a power semiconductor element disposed on the mounting substrate 11. Specifically, the semiconductor chip 12 is bonded by a joining material 151 such as solder or a sintered material, etc., to the conductive pattern 113. The semiconductor chip 12 functions as a switching element that can switch between flow of electricity and interruption of electricity. In the first embodiment, the semiconductor chip 12 is an insulated gate bipolar transistor (IGBT), for example.

The semiconductor chip 12 includes a first electrode 121, a second electrode 122, and a control electrode (not shown). The first electrode 121 and the second electrode 122 are electrodes configured to receive and output a current as a control target. The first electrode 121 is a collector electrode that constitutes a lower surface of the semiconductor chip 12. The first electrode 121 is electrically connected to the conductive pattern 113. The second electrode 122 is an emitter electrode that constitutes an upper surface of the semiconductor chip 12. The control electrode is a gate electrode to which a control voltage is applied for control to turn the semiconductor chip 12 on and off. The control electrode as well as the second electrode 122 constitutes the upper surface of the semiconductor chip 12.

Each of the plurality of connection terminals 13 is a conductor that is electrically connected to the semiconductor chip 12. Specifically, each of the plurality of connection terminals 13 is a lead frame for electrically connecting the semiconductor chip 12 to an external device (not shown). Each of the plurality of connection terminals 13 is made of a conductive material such as a copper material alone or an alloy of copper, etc. The plurality of connection terminals 13 includes a connection terminal 13a that is bonded by a joining material 152 to the second electrode 122 of the semiconductor chip 12. The plurality of connection terminals 13 further includes a connection terminal 13b that is bonded by a joining material 153 to the conductive pattern 113. The joining material 152 and the joining material 153 are each a conductive material such as solder or a sintered material, etc.

The encapsulant 14 is a molded object with insulation. The encapsulant 14 encapsulates the semiconductor chip 12. The encapsulant 14 is made of a rigid resin material such as an epoxy resin material. In the first embodiment, the encapsulant 14 is a substantially rectangular parallelepiped-shaped structure that includes a top surface 141, a rear surface 142, and a side surface 143. The top surface 141 is an upper surface facing in the direction Z2, and the rear surface 142 is a lower surface facing in the direction Z1. The side surface 143 is an edge surface connecting the top surface 141 and the rear surface 142 to each other. Each of the plurality of connection terminals 13 protrudes from the side surface 143 of the encapsulant 14. Each of the plurality of connection terminals 13 has a distal part that is bent in the direction Z2.

The metallic layer 112 has a front surface that is exposed from the rear surface 142 of the encapsulant 14. In FIG. 1, the semiconductor module 10 has a first surface F1 that is a rectangular lower surface facing in the direction Z1. The first surface F1 is constituted of the front surface of the metallic layer 112 and the rear surface 142 of the encapsulant 14.

In FIG. 1, the cooler 20 is a structure configured to cool the semiconductor module 10. The cooler 20 is, for example, a heat radiating plate configured to radiate away heat conducted from the semiconductor module 10. Alternatively, the cooler 20 may be a heat sink provided with a plurality of fins, or a water jacket provided with a flow path through which refrigerant such as cooling water flows. In FIG. 1, the cooler 20 has a second surface F2 that is a rectangular upper surface facing in the direction Z2.

The thermal conductive layer 30 is a rectangular film that is interposed between the semiconductor module 10 and the cooler 20. The thermal conductive layer 30 is, for example, a thin plate-shaped layer, a sheet-shaped layer, or a film-shaped layer. The thermal conductive layer 30 is interposed between the semiconductor module 10 and the cooler 20. The first surface F1 of the semiconductor module 10 and the second surface F2 of the cooler 20 face each other across the thermal conductive layer 30. The thermal conductive layer 30 functions as an adhesive layer that bonds the first surface F1 and the second surface F2 to each other. The thermal conductive layer 30 has an appropriate thickness of 10 micrometers or more and 300 micrometers or less.

The thermal conductive layer 30 is made of a material with high thermal conductivity. Specifically, the thermal conductive layer 30 is made of, for example, a thermosetting resin material such as an epoxy resin material, a polyimide resin material, etc., or a thermoplastic resin material such as an olefin material. For example, in the thermal conductive layer 30, fillers may be dispersed, the filler being made of a silver material, an aluminum material, a copper material, a silicon oxide material (SiO₂), an aluminum oxide material (Al₂O₃), a boron nitride material, an aluminum nitride material, or a zinc oxide material, etc. The thermal conductive layer 30 is basically constituted of a single layer. However, the thermal conductive layer 30 may be a stack of a plurality of layers made of different materials.

In the above configuration, heat generated by the semiconductor chip 12 is conducted to the cooler 20 via the mounting substrate 11 and the thermal conductive layer 30. The thermal conductive layer 30 functions as a heat radiation layer for conducting heat from the semiconductor module 10 to the cooler 20.

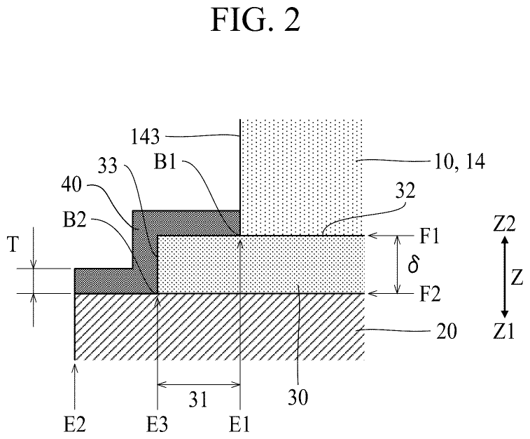

FIG. 2 is an enlarged cross section of a vicinity of an outer peripheral edge E1 of the semiconductor module 10. FIG. 2 shows a region a shown in FIG. 1. As shown in FIG. 2, the thermal conductive layer 30 has an outer peripheral edge E3 that is, in plan view, interposed between the outer peripheral edge E1 of the semiconductor module 10 and an outer peripheral edge E2 of the cooler 20. Specifically, the thermal conductive layer 30 has a diameter that is greater than a diameter of the first surface F1 of the semiconductor module 10, and the outer peripheral edge E1 of the first surface F1 is disposed inside the outer peripheral edge E3 of the thermal conductive layer 30. In addition, the second surface F2 of the cooler 20 has a diameter that is greater than the diameter of the thermal conductive layer 30, and the outer peripheral edge E2 of the second surface F2 is disposed outside the outer peripheral edge E3 of the thermal conductive layer 30. As shown in FIG. 2, the thermal conductive layer 30 has an outer peripheral portion 31 that is, in plan view, disposed outside the outer peripheral edge E1 of the semiconductor module 10.

The protective film 40 is a covering film for substantially preventing infiltration of moisture into an object (and into gaps) interposed between the semiconductor module 10 and the cooler 20. In the first embodiment, the protective film 40 covers and seals an area in which the semiconductor module 10 and the cooler 20 are bonded to each other. Specifically, the protective film 40 covers a boundary B1 between the semiconductor module 10 and the thermal conductive layer 30, and a boundary B2 between the cooler 20 and the thermal conductive layer 30.

The boundary B1 is a boundary between the semiconductor module 10 and the thermal conductive layer 30. Specifically, the boundary B1 is an area in which the side surface 143 of the semiconductor module 10 and an upper surface 32 of the thermal conductive layer 30 intersect with each other. The boundary B2 is a boundary between the cooler 20 and the thermal conductive layer 30. Specifically, the boundary B2 is an area in which the second surface F2 of the cooler 20 and a side surface 33 of the thermal conductive layer 30 intersect with each other.

The protective film 40 spreads from the side surface 143 of the semiconductor module 10 to the second surface F2 of the cooler 20 so as to cover both the boundary B1 and the boundary B2. Thus, the protective film 40 covers the outer peripheral portion 31 of the thermal conductive layer 30. The protective film 40 may be referred to as a covering film for protecting the thermal conductive layer 30, as a covering film for protecting connection of the thermal conductive layer 30 to the semiconductor module 10, or as a covering film for protecting connection of the thermal conductive layer 30 to the cooler 20.

The protective film 40 is made of a material having water resistance and moisture resistance that are higher than those of the thermal conductive layer 30. Specifically, the protective film 40 is made of a resin material such as a urethane resin material, a fluoropolymer material, or a polyimide resin material, etc. As the urethane resin material, an ether urethane resin material is preferably used that has water resistance and moisture resistance that are particularly high. In the resin material of the protective film 40, fillers may be dispersed, the fillers being made of a silicon oxide material (SiO₂) or an aluminum oxide material (Al₂O₃), etc.

In a state in which the above materials are applied, the protective film 40 has a water absorption rate that is lower than a water absorption rate of the thermal conductive layer 30. The water absorption rate is the rate of weight of moisture that can be absorbed by an object relative to weight of the object. Thus, it is difficult for the protective film 40 to absorb moisture compared to the thermal conductive layer 30.

As shown in FIG. 2, the protective film 40 has a thickness T that is less than a distance δ between the semiconductor module 10 and the cooler 20 (T<δ). The thickness T of the protective film 40 is an average thickness of the protective film 40 in a direction of the Z-axis. The distance δ is a distance between the first surface F1 and the second surface F2. The thickness of the thermal conductive layer 30 is equal to the distance γ. Thus, the thickness T of the protective film 40 is less than the thickness of the thermal conductive layer 30.

As described above, in the first embodiment, the boundary B1 between the semiconductor module 10 and the thermal conductive layer 30, and the boundary B2 between the cooler 20 and the thermal conductive layer 30 are covered with the protective film 40. Thus, it is possible to substantially prevent infiltration of moisture into the object (and into gaps) interposed between the semiconductor module 10 and the cooler 20. For example, infiltration of moisture into the boundary B1 (gap) is substantially prevented. As a result, it is possible to substantially prevent reduction in bonding of the semiconductor module 10 (the first surface F1) to the thermal conductive layer 30. Similarly, infiltration of moisture into the boundary B2 (gap) is substantially prevented. As a result, it is possible to substantially prevent reduction in bonding of the cooler 20 (the second surface F2) to the thermal conductive layer 30.

In the first embodiment, the water absorption rate of the protective film 40 is less than the water absorption rate of the thermal conductive layer 30. Thus, compared to a configuration in which the water absorption rate of the protective film 40 is greater than the water absorption rate of the thermal conductive layer 30, it is possible to substantially prevent infiltration of moisture into the thermal conductive layer 30. In other words, it is possible to substantially prevent infiltration of moisture into the object interposed between the semiconductor module 10 and the cooler 20. Thus, it is possible to substantially prevent degradation of the thermal conductive layer 30 due to the thermal conductive layer 30 absorbing water. For example, it is possible to substantially prevent degradation of insulation of the thermal conductive layer 30 due to the thermal conductive layer 30 absorbing water. Thus, it is possible to substantially prevent reduction in dielectric strength voltage of the semiconductor device 100. In addition, it is possible to substantially prevent degradation of heat radiation of the thermal conductive layer 30 due to the thermal conductive layer 30 absorbing water. Thus, it is possible to substantially prevent degradation of heat radiation of the semiconductor device 100.

### Method for Producing Semiconductor Device 100

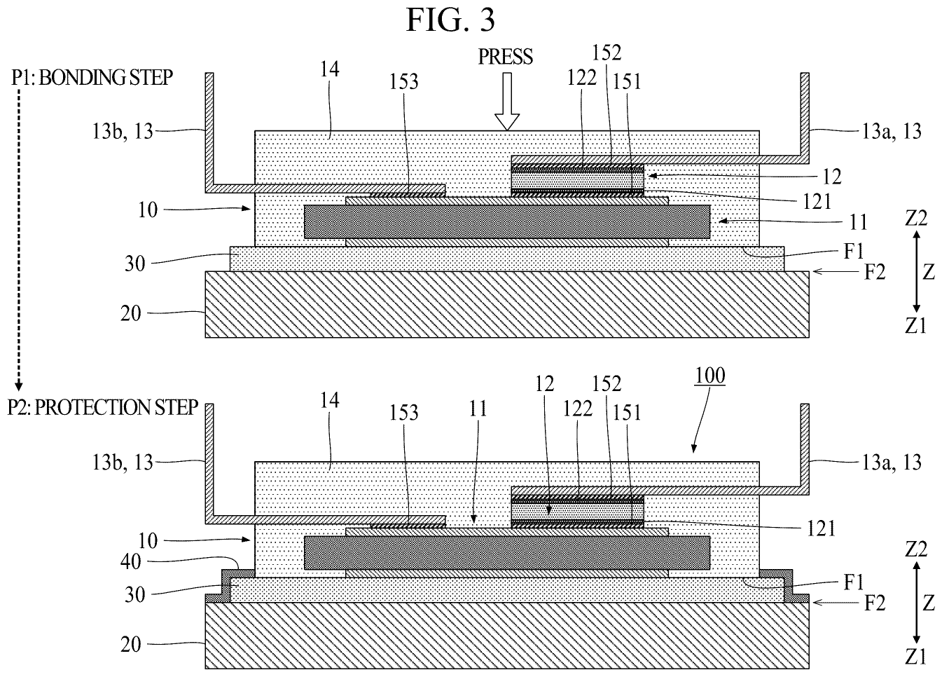

FIG. 3 is an explanatory diagram showing a process of producing the semiconductor device 100 described above. As shown in FIG. 3, the process of producing the semiconductor device 100 includes a bonding step P1 and a protection step P2.

In the bonding step P1, the semiconductor module 10 and the cooler 20 are bonded by the thermal conductive layer 30 to each other. Specifically, in the bonding step P1, with the thermal conductive layer 30 being interposed between the semiconductor module 10 and the cooler 20, the semiconductor module 10 or the cooler 20 is pressed toward the other. The bonding step P1 is carried out in a high temperature environment in which the thermal conductive layer 30 is heated. By the heating and pressing described above, the semiconductor module 10 and the cooler 20 is bonded by the thermal conductive layer 30 to each other.

After the bonding step P1 is completed, the protection step P2 is carried out. In the protection step P2, the protective film 40 is formed to cover the boundary B1 and the boundary B2. In the protection step P2, a liquid material having a low viscosity is applied and cured to form the protective film 40. Specifically, in the protection step P2, a viscosity of the liquid material before being cured is less than or equal to 3 pascal second, for example. As described above, the liquid material having the low viscosity is applied and cured, resulting in forming a uniform protective film 40 over a broad area.

To form the protective film 40 in the protection step P2, for example, spray coating may be used in which a liquid resin material is emitted from a spray device so as to be applied and to be cured. Alternatively, to form the protective film 40, dispenser coating may be used in which a liquid resin material is dispensed from a dispenser device so as to be applied and to be cured. The protective film 40 can be formed at low cost and be formed easily by the coating technique described above.

### B: Second Embodiment

A second embodiment according to this disclosure will be described. In the descriptions of the following embodiments, elements having the same functions as in the first embodiment are denoted by the same reference numerals used for like elements in the description of the first embodiment, and detailed description thereof is omitted, as appropriate.

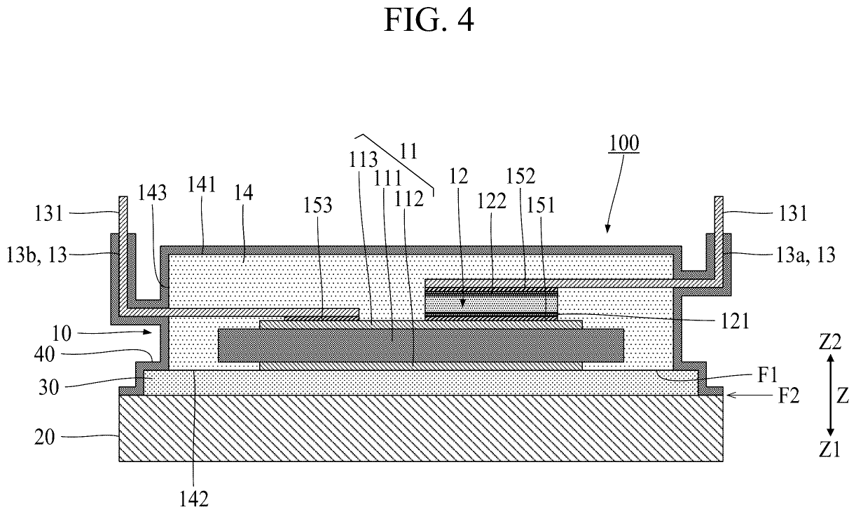

FIG. 4 is a cross section of the semiconductor device 100 according to the second embodiment. In the second embodiment, a configuration of the protective film 40 differs from that of the first embodiment. In the second embodiment, elements other than the protective film 40 are the same as those in the first embodiment.

As shown in FIG. 4, the protective film 40 according to the second embodiment covers the boundary B1 and the boundary B2 in the same manner as the first embodiment, and the protective film 40 according to the second embodiment further covers the entire encapsulant 14. Specifically, the protective film 40 covers the top surface 141 of the encapsulant 14 and the side surface 143 of the encapsulant 14, the top surface 141 being opposite to a surface of the encapsulant 14 facing the cooler 20. The protective film 40 covers the entire area of the top surface 141 and the entire area of the side surface 143.

The protective film 40 according to the second embodiment further covers a portion of each of the plurality of connection terminals 13 (13a, 13b). Specifically, the protective film 40 covers a portion of a connection terminal 13 that is each of the plurality of connection terminals 13, the portion of the connection terminal 13 being other than a distal portion 131 of the connection terminal 13. In other words, the protective film 40 is continuous from the side surface 143 of the encapsulant 14 to a surface of each of the plurality of connection terminals 13.

### Method for Producing Semiconductor Device 100

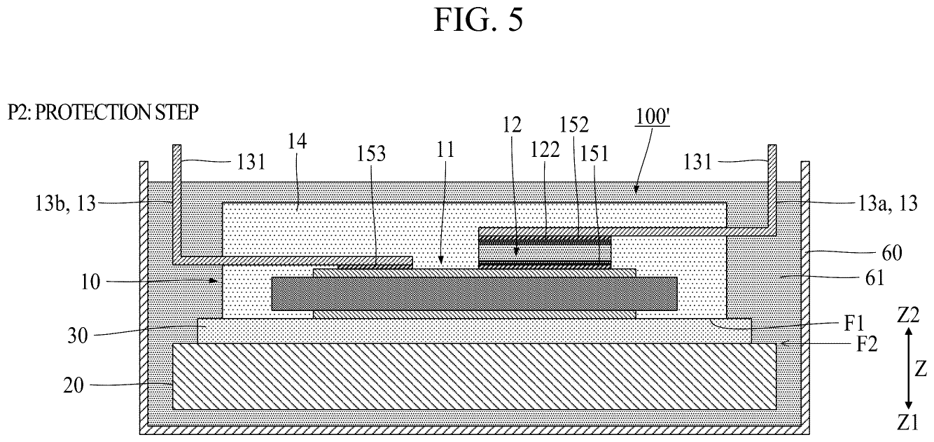

FIG. 5 is an explanatory diagram showing the protection step P2 of the process of producing the semiconductor device 100 according to the second embodiment. After the bonding step P1 as in the first embodiment is completed, the protection step P2 shown in FIG. 5 is carried out.

To form the protective film 40 according to the second embodiment, dip coating is used. In the dip coating, a liquid resin material 61 is used that is stored in a container 60. A viscosity of the resin material 61 stored in the container 60 is less than or equal to 3 pascal second, for example.

Specifically, in the protection step P2, a semiconductor device 100′ that is not provided with the protective film 40 is dipped into the resin material 61 in the container 60 such that the resin material 61 is applied to the semiconductor device 100′. For example, with the distal portion 131 of each of the plurality of connection terminals 13 being held, the semiconductor device 100′ is dipped into the resin material 61. Thus, the resin material 61 does not adhere to the distal portion 131 of each of the plurality of connection terminals 13. The resin material 61 applied in the above step is cured to form the protective film 40 shown in FIG. 4.

The second embodiment provides the same effects as those provided by the first embodiment. In the second embodiment, the protective film 40 covers not only the boundary B1 and the boundary B2, but also the top surface 141 and the side surface 143 that are included in the encapsulant 14 encapsulating the semiconductor chip 12. Thus, it is possible to efficiently prevent infiltration of moisture into the object (and into gaps) interposed between the semiconductor module 10 and the cooler 20. In the second embodiment, the protective film 40 is formed by dip coating. Thus, the protective film 40 can be formed at low cost and be formed easily as in the first embodiment in which the protective film 40 is formed by spray coating or by dispenser coating.

### C: Third Embodiment

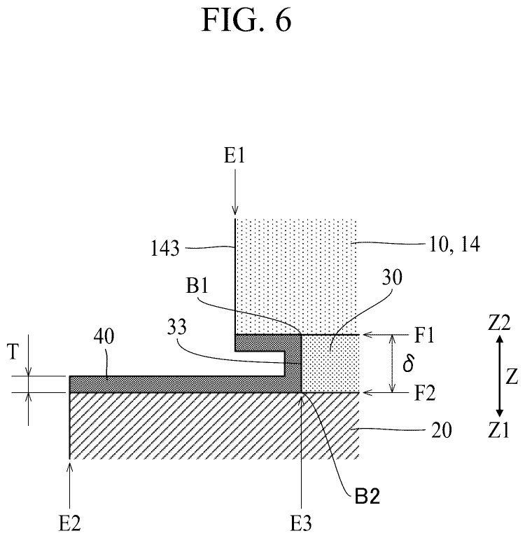

FIG. 6 is an enlarged cross section of a vicinity of the outer peripheral edge E1 of the semiconductor module 10 of the semiconductor device 100 according to a third embodiment. In the third embodiment, a configuration of the thermal conductive layer 30 and a configuration of the protective film 40 differ from those of the first embodiment. In the third embodiment, elements that are other than the thermal conductive layer 30 and that are other than the protective film 40 are the same as those of the first embodiment.

In the first embodiment, the outer peripheral edge E3 of the thermal conductive layer 30 is disposed outside the outer peripheral edge E1 of the semiconductor module 10. In the third embodiment, as shown in FIG. 6, the outer peripheral edge E3 of the thermal conductive layer 30 is disposed inside the outer peripheral edge E1 of the semiconductor module 10. In other words, the thermal conductive layer 30 according to the third embodiment does not include the outer peripheral portion 31 in the first embodiment.

As shown in FIG. 6, the boundary B1 between the semiconductor module 10 and the thermal conductive layer 30 is an area in which the first surface F1 of the semiconductor module 10 and the side surface 33 of the thermal conductive layer 30 intersect. The boundary B2 between the cooler 20 and the thermal conductive layer 30 is an area in which the second surface F2 of the cooler 20 and the side surface 33 of the thermal conductive layer 30 intersect, as in the first embodiment,

The protective film 40 according to the third embodiment covers the boundary B1 and the boundary B2 that are described above. Specifically, as shown in FIG. 6, the protective film 40 spreads over the first surface F1 of the semiconductor module 10, over the side surface 33 of the thermal conductive layer 30, and over the second surface F2 of the cooler 20. In other words, the protective film 40 according to the third embodiment has a portion that is disposed on a recess disposed between the first surface F1 and the second surface F2, the recess being disposed outside the thermal conductive layer 30.

In the third embodiment, a configuration in which the water absorption rate of the protective film 40 is less than the water absorption rate of the thermal conductive layer 30, and a configuration in which the thickness T of the protective film 40 is less than the distance δ between the semiconductor module 10 and the cooler 20 are the same as those of the first embodiment. A method for producing the semiconductor device 100 according to the third embodiment is the same as that of the first embodiment. Alternatively, the semiconductor device 100 according to the third embodiment may be produced by the producing method described in the second embodiment. The third embodiment provides the same effects as those provided by the first embodiment.

In contrast with the third embodiment described above, in the first embodiment, the outer peripheral portion 31 of the thermal conductive layer 30 is disposed outside the outer peripheral edge E1 of the semiconductor module 10, and the protective film 40 covers the outer peripheral portion 31 of the thermal conductive layer 30. Thus, compared to the third embodiment in which the outer peripheral edge E3 of the thermal conductive layer 30 is disposed inside the outer peripheral edge E1 of the semiconductor module 10, an advantage can be obtained in that it is possible to prevent more effectively infiltration of moisture into the object (and gaps) interposed between the semiconductor module 10 and the cooler 20.

### D: Modifications

Specific modified modes that may be applied to each of the embodiments described above are described below. Two or more modifications freely selected from the following modifications may be combined as long as no conflict arises from such combination.

(1) In each of the foregoing embodiments, a configuration is described in which the protective film 40 is constituted of a single layer. However, the protective film 40 may be constituted of a stack of a plurality of layers made of different materials. In each of the foregoing embodiments, a configuration is described in which the protective film 40 is made of a resin material. However, the material of the protective film 40 is not limited to the above example. For example, the protective film 40 may be made of an insulated inorganic material.

(2) The configuration of the semiconductor module 10 is not limited to the example in each of the foregoing embodiments. For example, the number of semiconductor chips 12, arrangement of the semiconductor chip 12, the number of conductive patterns 113, arrangement of the conductive pattern 113, the number of connection terminals 13, or arrangement of the connection terminals 13 may be freely changed from the example in each of the foregoing embodiments. The semiconductor module 10 may comprehensively be referred to as an element that includes the semiconductor chip 12.

(3) In each of the foregoing embodiments, a configuration is described in which the thickness T of the protective film 40 is less than the distance δ between the semiconductor module 10 and the cooler 20. However, a relationship between the thickness T and the interval δ is not limited to the above example. For example, a configuration is assumed in which the thickness T of the protective film 40 is equal to the distance δ (T=δ), or alternatively, a configuration is assumed in which the thickness T of the protective film 40 is greater than the distance δ (T>δ). Similarly, a configuration is assumed in which the thickness T of the protective film 40 is equal to the thickness of the thermal conductive layer 30, or alternatively, a configuration is assumed in which the thickness T of the protective film 40 is greater than the thickness of the thermal conductive layer 30.

(4) In each of the foregoing embodiments, a configuration is described in which the thermal conductive layer 30 is interposed between the semiconductor module 10 and the cooler 20, the thermal conductive layer 30 being a thin plate-shaped layer, a sheet-shaped layer, or a film-shaped layer. However, a configuration of the thermal conductive layer 30 is not limited to the above example. For example, to form the thermal conductive layer 30, a liquid resin material may be applied and be cured between the semiconductor module 10 and the cooler 20.

(5) The method for producing the protective film 40 is not limited to the method described in each of the foregoing embodiments. For example, to form the protective film 40 in the protection step P2, spin coating may be used in which the semiconductor device 100′ that is not provided with the protective film 40 is rotated to apply a liquid resin material over a wide area.

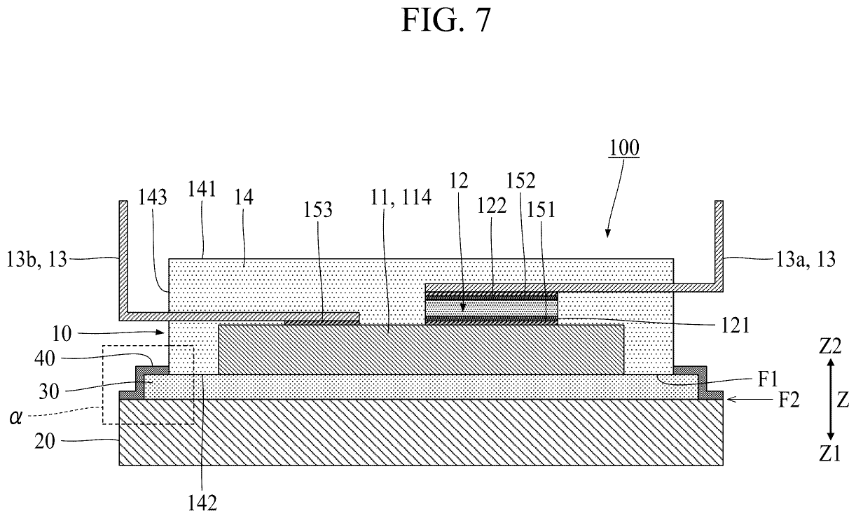

(6) In each of the foregoing embodiments, a configuration is described in which the mounting substrate 11 includes the stack of the insulated substrate 111, the metallic layer 112, and the conductive pattern 113. However, a configuration of the mounting substrate 11 is not limited to the above example. For example, as shown in FIG. 7, the mounting substrate 11 may be constituted of only a conductive pattern 114. The conductive pattern 114 has a front surface that is exposed from the rear surface 142 of the encapsulant 14. In FIG. 7, the first surface F1 is constituted of the front surface of the conductive pattern 114 and the rear surface 142 of the encapsulant 14. In FIG. 7, the mounting substrate 11 (conductive pattern 114) is made of a conductive material such as a copper material, an alloy of copper, an aluminum material, or an alloy of aluminum, etc.

As shown in FIG. 7, in a configuration in which the mounting substrate 11 does not have insulation, the thermal conductive layer 30 is made of an insulation material. Specifically, the thermal conductive layer 30 shown in FIG. 7 is made of, for example, a thermosetting resin material such as an epoxy resin material, a polyimide resin material, etc., or of a thermoplastic resin material such as an olefin material. In the thermal conductive layer 30, fillers may be dispersed, the fillers being made of a silicon oxide material (SiO₂), an aluminum oxide material (Al₂O₃), a boron nitride material, an aluminum nitride material, or a zinc oxide material, etc. The thermal conductive layer 30 is basically constituted of a single layer. However, the thermal conductive layer 30 may be a stack of a plurality of layers made of different materials.

In FIG. 7, a single conductive pattern 114 is shown as the mounting substrate 11 for convenience. However, in a configuration in which a plurality of semiconductor chips 12 are disposed, the mounting substrate 11 may be constituted of a plurality of conductive patterns 114.

(7) In each of the foregoing embodiments, an IGBT is described as an example of the semiconductor chip 12. However, a configuration of the semiconductor chip 12 and a type of semiconductor chip 12 are not limited to the above example. For example, the semiconductor chip 12 may be a reverse conducting insulated gate bipolar transistor (RC-IGBT) that includes both an IGBT and a freewheeling diode (FWD). The semiconductor chip 12 may be a metal oxide semiconductor field effect transistor (MOSFET) having a semiconductor layer made of a silicon (Si) material or of a silicon carbide (SiC) material. In a configuration in which the semiconductor chip 12 is constituted of a MOSFET, the first electrode 121 is a drain electrode, whereas the second electrode 122 is a source electrode. The semiconductor chip 12 is not limited to transistors. For example, the semiconductor chip 12 may be diodes such as a Schottky Barrier Diode (SBD).

### E: Supplemental Notes

The following configurations are derivable from the foregoing embodiments.

A semiconductor device according to one aspect (first aspect) of this disclosure includes: a semiconductor module including a semiconductor chip; a cooler configured to cool the semiconductor module; a thermal conductive layer interposed between the semiconductor module and the cooler; and a protective film covering: a boundary between the semiconductor module and the thermal conductive layer; and a boundary between the cooler and the thermal conductive layer, in which the protective film has a water absorption rate that is less than a water absorption rate of the thermal conductive layer. According to this aspect, the boundary between the semiconductor module and the thermal conductive layer and the boundary between the cooler and the thermal conductive layer are covered with the protective film. Thus, it is possible to substantially prevent infiltration of moisture into an object (or into gaps) interposed between the semiconductor module and the cooler. The water absorption rate of the protective film is less than the water absorption rate of the thermal conductive layer. Thus, compared to a configuration in which the water absorption rate of the protective film is greater than the water absorption rate of the thermal conductivity layer, an advantage is significant in that it is possible to substantially prevent infiltration of moisture into an object (or into gaps) interposed between the semiconductor module and the cooler.

A semiconductor device according to another aspect (second aspect) of this disclosure includes: a semiconductor module including a semiconductor chip; a cooler configured to cool the semiconductor module; a thermal conductive layer interposed between the semiconductor module and the cooler; and a protective film covering: a boundary between the semiconductor module and the thermal conductive layer; and a boundary between the cooler and the thermal conductive layer, in which the protective film has a thickness that is less than a distance between the semiconductor module and the cooler. According to this aspect, the boundary between the semiconductor module and the thermal conductive layer and the boundary between the cooler and the thermal conductive layer are covered with the protective film. Thus, it is possible to substantially prevent infiltration of moisture into an object (or into gaps) interposed between the semiconductor module and the cooler.

In a specific example (third aspect) of the second aspect, the protective film has a water absorption rate that is less than a water absorption rate of the thermal conductive layer. According to this aspect, the water absorption rate of the protective film is less than the water absorption rate of the thermal conductive layer. Thus, compared to a configuration in which the water absorption rate of the protective film is greater than the water absorption rate of the thermal conductivity layer, an advantage is significant in that it is possible to substantially prevent infiltration of moisture into an object (or into gaps) interposed between the semiconductor module and the cooler.

In a specific example (fourth aspect) of any one of the first to third aspects, the thermal conductive layer includes an outer peripheral portion disposed outside an outer peripheral edge of the semiconductor module in plan view, and the protective film further covers the outer peripheral portion of the thermal conductive layer. According to this aspect, the outer peripheral portion of the thermal conductive layer is disposed outside the outer peripheral edge of the semiconductor module, and the protective film further covers the outer peripheral portion. Thus, compared to a configuration in which an outer peripheral edge of the thermal conductive layer is disposed inside the outer peripheral edge of the semiconductor module, it is possible to efficiently prevent infiltration of moisture into an object (or into gaps) interposed between the semiconductor module and the cooler.

In a specific example (fifth aspect) of any one of the first to fourth aspects, the semiconductor module further includes: an encapsulant encapsulating the semiconductor chip; and a connection terminal electrically connected to the semiconductor chip, the connection terminal protruding from the encapsulant, and the protective film further covers a front surface of the encapsulant and a side surface of the encapsulant, the front surface of the encapsulant being opposite to a surface of the encapsulant facing the cooler. According to this aspect, the protective film covers not only the boundary between the semiconductor module and the thermal conductive layer and the boundary between the cooler and the thermal conductive layer, but also the front surface of the encapsulant encapsulating the semiconductor chip and the side surface of the encapsulant. Thus, it is possible to more efficiently prevent infiltration of moisture into an object (or into gaps) interposed between the semiconductor module and the cooler. In addition, the protective film can be formed at low cost and readily by dipping the semiconductor module into a liquid resin material.

In a specific example (sixth aspect) of any one of the first to fifth aspects, the protective film includes a urethane resin material, a fluoropolymer material, or a polyimide resin material. As the urethane resin material, an ether urethane resin material is preferably used that has water resistance and moisture resistance that are particularly high.

A production method according to one aspect (seventh aspect) of this disclosure includes: bonding a semiconductor module including a semiconductor chip to a cooler configured to cool the semiconductor module by a thermal conductive layer interposed between the semiconductor module and the cooler; and forming a protective film covering: a boundary between the semiconductor module and the thermal conductive layer; and a boundary between the cooler and the thermal conductive layer. According to this aspect, the boundary between the semiconductor module and the thermal conductive layer and the boundary between the cooler and the thermal conductive layer are covered with the protective film. Thus, it is possible to substantially prevent infiltration of moisture into an object (or into gaps) interposed between the semiconductor module and the cooler.

In a specific example (eighth aspect) of the seventh aspect, the forming of the protective film includes forming the protective film by spray coating, by dip coating, by dispenser coating, or by spin coating. According to this aspect, the protective film can be formed at low cost and be formed easily by a coating technique such as spray coating, dip coating, dispenser coating, or spin coating.

In a specific example (ninth aspect) of the seventh aspect or the eighth aspect, the forming of the protective film includes forming the protective film by applying a liquid material having a viscosity that is less than or equal to 3 pascal second and curing the liquid material. According to this aspect, by applying and curing the liquid material having the viscosity that is less than or equal to 3 pascal second, a uniform protective film can be formed over a broad area.

### DESCRIPTION OF REFERENCE SIGNS

100 . . . semiconductor device, 10 . . . semiconductor module, 11 . . . mounting substrate, 111 . . . insulated substrate, 112 . . . metallic layer, 113, 114 . . . conductive pattern, 12 . . . semiconductor chip, 121 . . . first electrode, 122 . . . second electrode, 13 (13a, 13b) . . . connection terminal, 14 . . . encapsulant, 141 . . . top surface, 142 . . . rear surface, 143 . . . side surface, 151, 152, 153 . . . joining material, 20 . . . cooler, 30 . . . thermal conductive layer, 31 . . . outer peripheral portion, 32 . . . upper surface, 33 . . . side surface, 40 . . . protective film, F1 . . . first surface, F2 . . . second surface, B1, B2 . . . boundary.

What is claimed is:

1. A semiconductor device comprising:
a semiconductor module including a semiconductor chip;
a cooler configured to cool the semiconductor module;
a thermal conductive layer interposed between the semiconductor module and the cooler; and
a protective film covering:
a boundary between the semiconductor module and the thermal conductive layer; and
a boundary between the cooler and the thermal conductive layer,
wherein the protective film has a water absorption rate that is less than a water absorption rate of the thermal conductive layer.

2. A semiconductor device comprising:
a semiconductor module including a semiconductor chip;
a cooler configured to cool the semiconductor module;
a thermal conductive layer interposed between the semiconductor module and the cooler; and
a protective film covering:
a boundary between the semiconductor module and the thermal conductive layer; and
a boundary between the cooler and the thermal conductive layer,
wherein the protective film has a thickness that is less than a distance between the semiconductor module and the cooler.

3. The semiconductor device according to claim 2, wherein the protective film has a water absorption rate that is less than a water absorption rate of the thermal conductive layer.

4. The semiconductor device according to claim 1,
wherein the thermal conductive layer includes an outer peripheral portion disposed outside an outer peripheral edge of the semiconductor module in plan view, and
wherein the protective film further covers the outer peripheral portion of the thermal conductive layer.

5. The semiconductor device according to claim 1,
wherein the semiconductor module further comprises:
an encapsulant encapsulating the semiconductor chip; and
a connection terminal electrically connected to the semiconductor chip, the connection terminal protruding from the encapsulant, and
wherein the protective film further covers a front surface of the encapsulant and a side surface of the encapsulant, the front surface of the encapsulant being opposite to a surface of the encapsulant facing the cooler.

6. The semiconductor device according to claim 1, wherein the protective film includes a urethane resin material, a fluoropolymer material, or a polyimide resin material.

7. A method for producing a semiconductor device, the method comprising:
bonding a semiconductor module including a semiconductor chip to a cooler configured to cool the semiconductor module by a thermal conductive layer interposed between the semiconductor module and the cooler; and
forming a protective film covering:
a boundary between the semiconductor module and the thermal conductive layer; and
a boundary between the cooler and the thermal conductive layer.

8. The method according to claim 7, wherein the forming of the protective film includes forming the protective film by spray coating, by dip coating, by dispenser coating, or by spin coating.

9. The method according to claim 7, wherein the forming of the protective film includes forming the protective film by applying a liquid material having a viscosity that is less than or equal to 3 pascal second and curing the liquid material.
